(19) United States
(12) Patent Application Publication
(10) Pub. No.: US 2013/0000696 A1
(43) Pub. Date: Jan. 3, 2013

(54) PHOTOVOLTAIC SYSTEMS AND METHODS

(75) Inventor: Sandeep K. Giri, Mountain View, CA (US)

(73) Assignee: QUALCOMM MEMS Technologies, Inc., San Diego, CA (US)

(21) Appl. No.: 13/306,786

(22) Filed: Nov. 29, 2011

Related U.S. Application Data
(60) Provisional application No. 61/503,097, filed on Jun. 30, 2011.

(51) Int. Cl. H01L 31/042

(52) U.S. Cl. 136/246

(57) ABSTRACT

This disclosure provides methods and apparatus for increasing the efficiency of a photovoltaic module. In one aspect, the position of a photovoltaic panel can be updated throughout the day based on whether the solar angle of incidence on the panel falls within a cone of at least 10° about a normal of the panel. For example, the panel can remain stationary when the solar angle of incidence falls within the cone, but when the solar angle of incidence falls outside the cone, the panel can be moved so that the solar angle of incidence falls within the cone.

### CROSS-REFERENCE TO RELATED APPLICATIONS

This disclosure claims priority to U.S. Provisional Patent Application No. 61/503,097, filed Jun. 30, 2011, entitled “Light Harvesting in Photovoltaic Systems,” and assigned to the assignee hereof. The disclosure of the prior application is considered part of, and is incorporated by reference in, this disclosure.

### TECHNICAL FIELD

This disclosure relates generally to the field of optoelectronic devices that convert optical energy into electrical energy, for example, photovoltaic devices.

### DESCRIPTION OF THE RELATED TECHNOLOGY

For over a century fossil fuel such as coal, oil, and natural gas has provided the main source of energy in the United States. The need for alternative sources of energy is increasing. Fossil fuels are a non-renewable source of energy that is depleting rapidly. The large scale industrialization of developing nations such as India and China has placed a considerable burden on the availability of fossil fuel. In addition, geopolitical issues can quickly affect the supply of such fuel. Global warming is also of greater concern in recent years. A number of factors are thought to contribute to global warming; however, widespread use of fossil fuels is presumed to be a main cause of global warming. Thus there is an urgent need to find a renewable and economically viable source of energy that is also environmentally safe. Solar energy is an environmentally friendly renewable source of energy that can be converted into other forms of energy such as heat and electricity.

Photovoltaic cells convert optical energy to electrical energy and thus can be used to convert solar energy into electrical power. Photovoltaic solar cells can be made very thin and modular. Photovoltaic cells can range in size from a about few millimeters to tens of centimeters, or larger. The individual electrical output from one photovoltaic cell may range from a few milliwatts to a few watts. Several photovoltaic cells may be connected electrically and packaged in arrays to produce a sufficient amount of electricity. Photovoltaic cells can be used in a wide range of applications such as providing power to satellites and other spacecraft, providing electricity to residential and commercial properties, charging automobile batteries, etc.

While photovoltaic devices have the potential to reduce reliance upon fossil fuels, the widespread use of photovoltaic devices has been hindered by inefficiency concerns and concerns regarding the material costs required to produce such devices. Accordingly, improvements in efficiency and/or manufacturing costs could increase usage of photovoltaic devices.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of producing power from a photovoltaic panel. The method includes providing the photovoltaic panel, at least a portion of the photovoltaic panel defining a plane, the plane defining a normal. The method also includes updating the position of the panel during at least a portion of a day, the portion of the day including solar noon, wherein updating the position of the panel is based upon whether the solar angle of incidence on the panel falls within a cone defined by an angle of at least 10° about the normal such that when the solar angle of incidence falls within the cone, the panel remains stationary, and when the solar angle of incidence falls outside the cone, the panel is moved so that the solar angle of incidence falls within the cone. Updating the position of the panel can include rotating the panel about at least a first axis. The first axis can extend in a north-south plane. The first axis can extend in a horizontal direction. Updating the position of the panel can include rotating the panel about a second axis. The second axis can extend in an east-west plane. The second axis can extend in a vertical direction. The cone can be defined by an angle of about 10° about the normal. The cone can be defined by an angle of about 20° about the normal. The cone can be defined by an angle of about 30° about the normal. The portion of the day can include at least four hours. The portion of the day can include at least eight hours. The portion of the day can include at least twelve hours. The photovoltaic panel can include one or more diffusers. The one or more diffusers can be Lambertian or near-Lambertian diffusers. The one or more diffusers can account for at least 5% of a light-receiving surface area of the photovoltaic panel. The diffusers can account for between about 10% and 20% of a light-receiving surface area of the photovoltaic panel. 18. The one or more diffusers can be configured to reflect more light at an angle greater than about 45° from the normal than to reflect light at an angle that is less than about 45° from the normal. An amount of power collected for the portion of the day can be increased by at least 3% as compared to a method which moves an array of solar cells so that the array is oriented directly at the sun for the portion of the day.

Another innovative aspect of the subject matter described in this disclosure can be implemented in a method of producing power from a photovoltaic panel. The method includes providing the photovoltaic panel, at least a portion of the photovoltaic panel defining a plane, the plane defining a normal. The method also includes updating the position of the panel during at least a portion of a day based upon the solar angle of incidence on the panel, the portion of the day including solar noon, wherein when the solar angle of incidence falls within a zone defined by first and second cones about the normal axis, the panel remains stationary, and when the solar angle of incidence falls outside the zone, the panel is moved so that the solar angle of incidence falls within the zone. The first cone can be defined by an angle of at least 4.3° about the normal and the second cone can be defined by an angle of less than 5.3° about the normal. The first cone can be defined by an angle of at least 3.8° about the normal and the second cone can be defined by an angle of less than 5.8° about the normal. Updating the position of the panel can include rotating the panel about at least a first axis. The first axis can extend in a north-south plane. Updating the position of the panel can include rotating the panel about a second axis. The second axis can extend in an east-west plane.

A further innovative aspect of the subject matter described in this disclosure can be implemented in a system for producing electricity. The system includes means for converting solar radiation to electricity, the converting means extending generally in a plane, the plane defining a normal. The system also includes means for updating the position of the converting means during at least a portion of a day, the portion of the day including solar noon, based on whether the solar angle of incidence on the plane falls within a cone of at least 10° about the normal such that when the solar angle of incidence falls within the cone, the converting means remains stationary, and when the solar angle of incidence falls outside the cone, the converting means is moved so that the solar angle of incidence falls within the cone. The cone can be defined by an angle selected from the group consisting of 10°, 20°, and 30° about the normal.

In another implementation, the method can further include moving the array so that an orientation of the array is maintained at an angle offset from the zenith angle of the sun for at least a portion of a day. For example, instead of a planar array being positioned such that it is normal on either an x or y axis, to a line from the array to the sun, the array can be positioned such that it is at an angle offset from such a line in either the x-axis or the y-axis, or both. In some implementations, the offset angle is between about one (1) degree and nine (9) degrees. In some implementations, the offset angle is between about three (3) degrees and seven (7) degrees, or between about four (4) degrees and six (degrees). In some implementations, the offset angle is about five (5) degrees.

In another implementation, a method of producing electricity from solar rays includes providing an array of solar cells and moving the array of solar cells so that an orientation of the array is maintained at an angle offset from the zenith angle of the sun for at least a portion of a day. The angle can be greater than about 3°, between about 3° and about 10°, between about 4° and about 6°, and/or about 4.8°. The angle can be fixed throughout the portion of the day, or variable throughout the portion of the day. The portion of the day can include at least 4 hours, at least 8 hours, at least 12 hours, or more. The solar cells can be photovoltaic cells. The array can be a planar array. The array can include one or more diffusers. The one or more diffusers can account for at least 10% of a surface area of the array. Moving the array can include rotating the array about an axis. The cells in the array can be moved collectively or individually. An amount of power collected for the portion of the day can be increased by at least 3% as compared to a method which moves an array of solar cells so that the array is oriented directly at the sun for the portion of the day.

In another aspect, a method of producing electricity from solar rays includes providing an array of solar cells, orienting the array so as to receive the solar rays at a non-zero angle of incidence, and moving the array of solar cells so as to maintain the non-zero angle of incidence for at least a portion of a day. The angle can be greater than about 3°.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A is an example of a cross-section of one implementation of a photovoltaic cell including a p-n junction.

FIG. 1B is an example of a block diagram that schematically illustrates a cross-section of one example of a photovoltaic cell including a deposited thin film photovoltaic active material.

FIGS. 2A and 2B are examples of schematic plan and isometric sectional views depicting an example solar photovoltaic device with reflective electrodes on the front side.

FIG. 3 schematically depicts an example of two photovoltaic cells connected by a tab or ribbon.

FIG. 4A is an example of a schematic plan view of an array of photovoltaic cells in a photovoltaic module.

FIG. 4B is an example of a schematic cross-sectional view of a photovoltaic device having a diffuser formed on or forward of a conductor in a photovoltaic cell within an array of photovoltaic cells in a module.

FIG. 5 is an example of a graph of experimental data showing the maximum power collected from two different configurations of photovoltaic modules, one without diffusers and one including diffusers, with both configurations aimed directly at the sun.

FIG. 6A is an example of a graph of modeled data showing the power collected from two different photovoltaic modules, one without diffusers and one including diffusers, as the angle of incidence of the sun on the modules changes.

FIG. 6B is a close-up of the portion of FIG. 6A indicated by dashed line 6B.

FIG. 7 is an example of a graph of experimental data showing the gain achieved by a photovoltaic module including diffusers, as compared to a photovoltaic module without diffusers, at various tilt angles relative to the sun.

FIGS. 8A-8C are examples of schematic drawings illustrating a fixed solar panel, a single-axis tracking panel, and a dual-axis tracking panel, respectively.

FIGS. 9A-9D are examples of graphs showing the path of the sun at various geographical locations, on various days of the year.

FIG. 10A is an example of a schematic drawing illustrating a cone about the normal of a solar panel, in accordance with an implementation.

FIG. 10B is an example of a schematic drawing illustrating a zone defined by first and second cones about the normal of a solar panel, in accordance with another implementation.

FIGS. 11A-11C are examples of schematic drawings illustrating a method for updating the position of a solar panel based upon whether the solar angle of incidence on the panel falls within a cone about the normal, in accordance with an implementation.

FIGS. 12A-12C are examples of schematic drawings illustrating a method for updating the position of a solar panel based upon whether the solar angle of incidence on the panel falls within a zone defined by first and second cones about the normal, in accordance with another implementation.

FIGS. 13A and 13B are examples of process diagrams illustrating methods for producing power from a photovoltaic panel in accordance with some implementations.

FIG. 14 shows an example of a system block diagram illustrating a solar tracking system in accordance with one implementation.

Like reference numbers and designations in the various drawings indicate like elements.

### DETAILED DESCRIPTION

Implementations of a photovoltaic (PV) apparatus and methods disclosed herein include PV modules that include an array of photovoltaic devices (such as photovoltaic cells). In some implementations, a PV module or panel, which can include one or more diffusers, can be oriented so as to receive solar rays at a non-zero angle of incidence. In some implementations, the position of a PV panel can be updated throughout the day based on whether the solar angle of incidence on the panel falls within a cone of at least 10° about a normal of the panel. For example, the panel can remain stationary when the solar angle of incidence falls within the cone, but when the solar angle of incidence falls outside the cone, the panel can be moved so that the solar angle of incidence falls within the cone. In some implementations, the position of the PV panel can be updated throughout the day based on whether the solar angle of incidence on the panel falls within a zone defined by inner and outer cones about a normal of the panel.

Particular implementations of the subject matter described in this disclosure can be implemented to realize one or more of the following potential advantages. In some implementations, the total power generated by a photovoltaic module with diffusers formed in front of non-electricity-generating areas can be improved compared to a photovoltaic module without diffusers. Diffusers can allow for recapture of light that otherwise would have been lost and can also reduce the sensitivity of the photovoltaic module to the angle of incidence of incoming solar rays. Some implementations can achieve maximum power by orienting the panel or module at an angle offset from the sun. Some implementations can be used to increase the efficiency of a tracking PV panel, for example by updating the position of a tracking panel less frequently than conventional systems and taking advantage of the increase in power which results from orienting a PV panel with diffusers at an offset angle from the sun. Such an implementation can not only increase the power generated by the panel itself, but can also reduce the energy requirements of the tracking system for the panel.

Although certain implementations and examples are discussed herein, it is understood that the inventive subject matter extends beyond the specifically disclosed implementations to other alternative implementations and/or uses of the invention and obvious modifications and equivalents thereof. It is intended that the scope of the inventions disclosed herein should not be limited by the particular disclosed implementations. Thus, for example, in any method or process disclosed herein, the acts or operations making up the method/process may be performed in any suitable sequence and are not necessarily limited to any particular disclosed sequence. Various aspects and features of the implementations have been described where appropriate. It is to be understood that not necessarily all such aspects or features may be achieved in accordance with any particular implementation. Thus, for example, it should be recognized that the various implementations may be carried out in a manner that achieves or optimizes one feature or group of features as taught herein without necessarily achieving other aspects or features as may be taught or suggested herein. The following detailed description is directed to certain specific implementations of the invention. However, the invention can be implemented in a multitude of different ways. The implementations described herein may be implemented in a wide range of devices that incorporate photovoltaic devices for conversion of optical energy into electrical current.

In this description, reference is made to the drawings wherein like parts are designated with like numerals throughout. As will be apparent from the following description, the implementations may be implemented in a variety of devices that include photovoltaic active material.

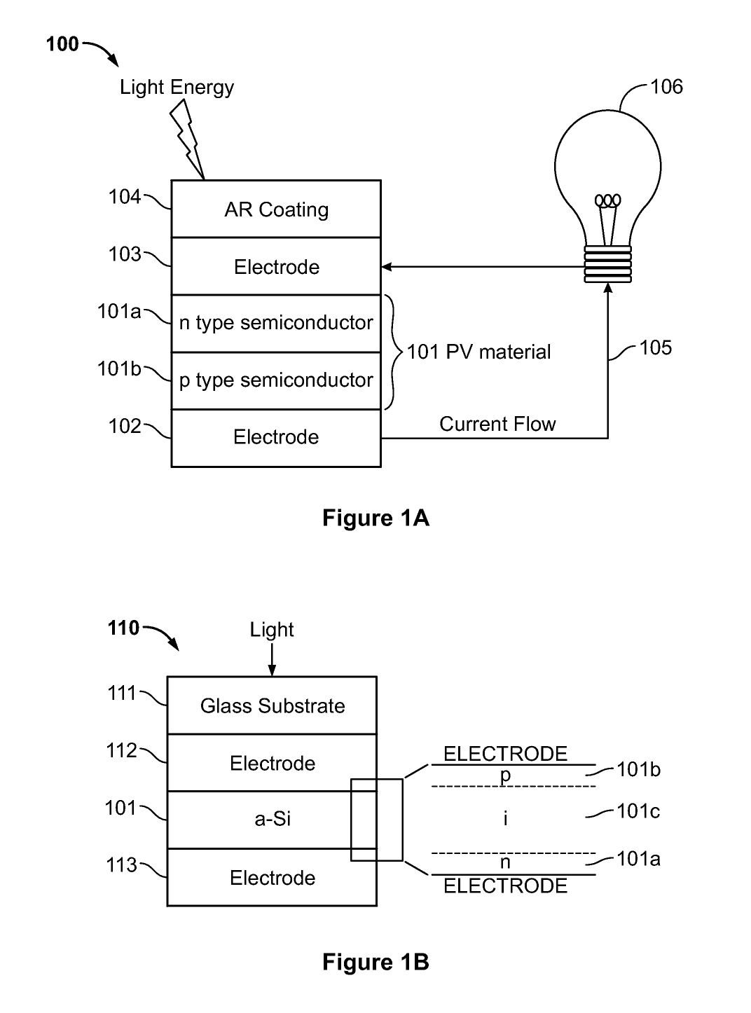

Turning now to the Figures, FIG. 1A is an example of a cross-section of one implementation of a photovoltaic cell including a p-n junction. A photovoltaic cell can convert light energy into electrical energy or current. A photovoltaic cell is an example of a renewable source of energy that has a small carbon footprint and has less impact on the environment. Using photovoltaic cells can reduce the cost of energy generation. Photovoltaic cells can have many different sizes and shapes, for example, from smaller than a postage stamp to several inches across. Several photovoltaic cells can often be connected together to form photovoltaic cell modules up to several feet long and several feet wide. Modules, in turn, can be combined and connected to form photovoltaic arrays of different sizes and power output.

The size of an array can depend on several factors, for example, the amount of sunlight available in a particular location and the needs of the consumer. The modules of the array can include electrical connections, mounting hardware, power-conditioning equipment, and batteries that store solar energy for use when the sun is not shining. A “photovoltaic device” as used herein can be a single photovoltaic cell (including its attendant electrical connections and peripherals), a photovoltaic module, a photovoltaic array, or solar panel. A photovoltaic device can also include functionally unrelated electrical components, such as components that are powered by the photovoltaic cell(s).

With reference to FIG. 1A, a photovoltaic cell 100 includes a photovoltaic active region 101 disposed between two electrodes 102, 103. In some implementations, the photovoltaic cell 100 includes a substrate on which a stack of layers is formed. The photovoltaic active layer 101 of a photovoltaic cell 100 may include a semiconductor material, for example, silicon. In some implementations, the active region may include a p-n junction formed by contacting an n-type semiconductor material 101a and a p-type semiconductor material 101b as shown in FIG. 1A. Such a p-n junction may have diode-like properties and may therefore be referred to as a photodiode structure as well.

The photovoltaic active material 101 is sandwiched between two electrodes that provide an electrical current path. The back electrode 102 can be formed of aluminum, silver, or molybdenum or some other conducting material. The front electrode 103 may be designed to cover a significant portion of the front surface of the p-n junction so as to lower contact resistance and increase collection efficiency. In implementations wherein the front electrode 103 is formed of an opaque material, the front electrode 103 may be configured to leave openings over the front of the photovoltaic active layer 101 to allow illumination to impinge on the photovoltaic active layer 101. In some implementations, the front and back electrodes 103, 102 can include a transparent conductor, for example, transparent conducting oxide (TCO), for example, aluminum-doped zinc oxide (ZnO:Al), fluorine-doped tin oxide (SnΘ₂:F), or indium tin oxide (ITO). The TCO can provide electrical contact and conductivity and simultaneously be transparent to incident radiation, including light. In some implementations, the front electrode 103 disposed between the source of light energy and the photovoltaic active material 101 can include one or more optical elements that redirect a portion of incident light. The optical elements can include, for example, diffusers, holograms, roughened interfaces, and/or diffractive optical elements including microstructures formed on various surfaces or formed within volumes. For example, roughened surface interfaces can be used to scatter light beams that pass therethrough. The scattering of light can increase the light absorbing path of the scattered light beams through the photovoltaic active material 101 and thus increase the electrical power output of the cell 100. In some implementations, the photovoltaic cell 100 can also include an anti-reflective (AR) coating 104 disposed over the front electrode 103. The AR coating 104 can reduce the amount of light reflected from the front surface of the photovoltaic active material 101.

When the front surface of the photovoltaic active material 101 is illuminated, photons transfer energy to electrons in the active region. If the energy transferred by the photons is greater than the band-gap of the semiconducting material, the electrons may have sufficient energy to enter the conduction band. An internal electric field is created with the formation of the p-n junction or p-i-n junction. The internal electric field operates on the energized electrons to cause these electrons to move, thereby producing a current flow in an external circuit 105. The resulting current flow can be used to power various electrical devices, for example, a light bulb 106 as shown in FIG. 1A, or to generate electricity for distribution to other devices, or to a distribution grid.

The photovoltaic active material layer(s) 101 can be formed by any of a variety of light absorbing, photovoltaic materials, for example, microcrystalline silicon (pc-silicon), amorphous silicon (a-silicon), cadmium telluride (CdTe), copper indium diselenide (CIS), copper indium gallium diselenide (CIGS), light absorbing dyes and polymers, polymers dispersed with light absorbing nanoparticles, III-V semiconductors, for example, gallium arsenide (GaAs), etc. Other materials may also be used. The light absorbing material(s) where photons are absorbed and transfer energy to electrical carriers (holes and electrons) is referred to herein as the photovoltaic active layer 101 or material of the photovoltaic cell 100, and this term is meant to encompass multiple active sub-layers. The material for the photovoltaic active layer 101 can be chosen depending on the desired performance and the application of the photovoltaic cell. In implementations where there are multiple active sublayers, one or more of the sublayers can include the same or different materials.

In some arrangements, the photovoltaic cell 100 can be formed by using thin film technology. For example, in one implementation, where optical energy passes through a transparent substrate, the photovoltaic cell 100 may be formed by depositing a first or front electrode layer 103 of TCO on a substrate. The substrate layer and the transparent conductive oxide layer 103 can form a substrate stack that may be provided by a manufacturer to an entity that subsequently deposits a photovoltaic active layer 101 thereon. After the photovoltaic active layer 101 has been deposited, a second electrode layer 102 can be deposited on the layer of photovoltaic active material 101. The layers may be deposited using deposition techniques including physical vapor deposition techniques, chemical vapor deposition techniques, for example, plasma-enhanced chemical vapor deposition, and/or electro-chemical vapor deposition techniques, etc. Thin film photovoltaic cells may include amorphous, monocrystalline, or polycrystalline materials, for example, silicon, thin-film amorphous silicon, CIS, CdTe or CIGS. Thin film photovoltaic cells facilitate small device footprint and scalability of the manufacturing process.

FIG. 1B is an example of a block diagram that schematically illustrates a cross-section of one example of a photovoltaic cell including a deposited thin film photovoltaic active material. The photovoltaic cell 110 includes a glass substrate layer 111 through which light can pass. Disposed on the glass substrate 111 are a first electrode layer 112, a photovoltaic active layer 101 (shown as including amorphous silicon), and a second electrode layer 113. The first electrode layers 112 can include a transparent conducting material, for example, ITO. As illustrated, the first electrode layer 112 and the second electrode layer 113 sandwich the thin film photovoltaic active layer 101 therebetween. The illustrated photovoltaic active layer 101 includes an amorphous silicon layer. As is known in the art, amorphous silicon serving as a photovoltaic material may include one or more diode junctions. Furthermore, an amorphous silicon photovoltaic layer or layers may include a p-i-n junction wherein a layer of intrinsic silicon 101c is sandwiched between a p-doped layer 101b and an n-doped layer 101a. A p-i-n junction may have higher efficiency than a p-n junction. In some other implementations, the photovoltaic cell 110 can include multiple junctions.

Photovoltaic cells can include a network of conductors that are disposed on the front surface of the cells and electrically connected to the photocurrent-generating substrate material. The conductors can be electrodes formed over the photovoltaic material of a photovoltaic device (including thin film photovoltaic devices) or the conductors may be tabs (ribbons) connecting individual devices together in a module and/or array. Photons entering a photovoltaic active material generate carriers throughout the material (except in the shadowed areas under the overlying conductors). The negatively and positively charged carriers (electrons and holes respectively), once generated, can travel only a limited distance through the photovoltaic active material before the carriers are trapped by imperfections in the substrates or recombine and return to a non-charged neutral state. The network of conductive carriers can collect current over substantially the entire surface of the photovoltaic device. Carriers can be collected by relatively thin lines at relatively close spacing throughout the surface of the photovoltaic device and the combined current from these thin lines can flow through a few sparsely spaced and wider width bus lines to the edge of the photovoltaic device.

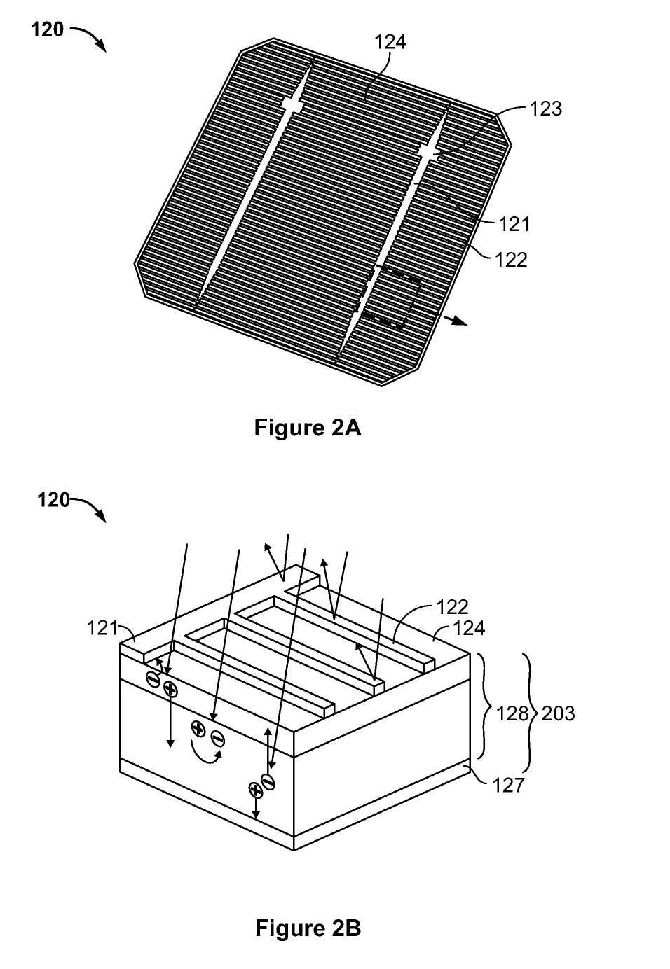

FIGS. 2A and 2B are examples of schematic plan and isometric sectional views depicting an example solar photovoltaic device with reflective electrodes on the front side. As illustrated in FIG. 2A, conductors on a light-incident or front side 124 of a device 120 can include larger bus electrodes 121 and/or smaller gridline electrodes 122. The bus electrodes 121 can also include larger pads 123 for soldering or electrically connecting a ribbon or tab (not shown). The electrodes 121, 122 can be patterned to reduce the distance an electron or hole travels to reach an electrode while also allowing enough light to pass through to the photovoltaic active layer(s). As illustrated in FIG. 2B, the photovoltaic device 120 can also include back electrodes 127, as well as a photovoltaic active region or photovoltaic active material 128 disposed between the front electrodes 121, 122 and the back electrodes 127.

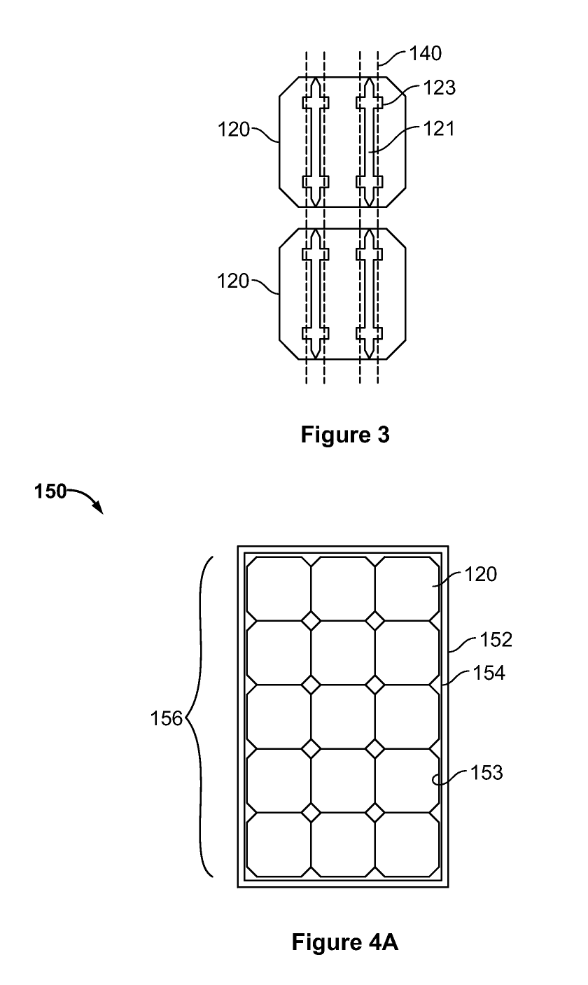

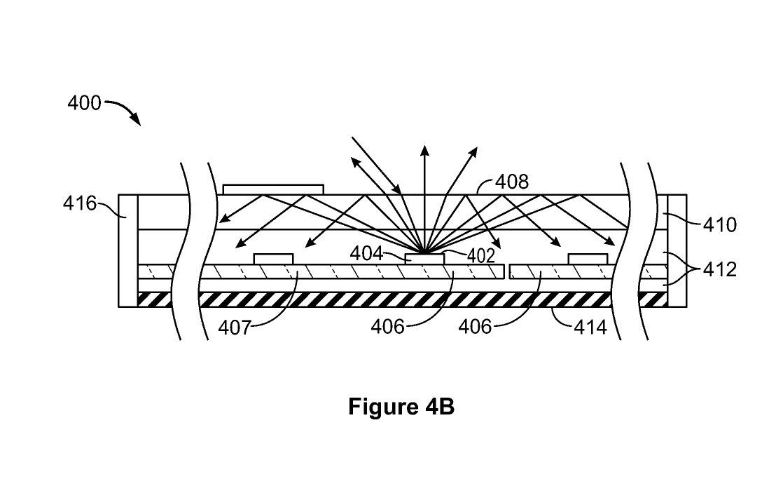

FIG. 3 schematically depicts an example of two photovoltaic cells connected by a tab or ribbon. In FIG. 3, two photovoltaic devices 120 are connected by a tab or ribbon 140. The ribbon 140 connects bus electrodes 121 or other electrodes across multiple photovoltaic devices 120, cells, dies, or wafers to form photovoltaic modules (as shown in FIG. 4), which can increase the output voltage by adding the voltage contributions of multiple photovoltaic devices 120 as may be desired according to the application. The ribbon 140 may be made of copper or other highly conductive material. This ribbon 140, like the bus 121 or gridline 122 electrodes, may reflect light, and may therefore also reduce the efficiency of the photovoltaic device 120.

FIG. 4A is an example of a schematic plan view of an array of a photovoltaic module 150 that includes a plurality of photovoltaic cells 120 arranged in an array 156. The photovoltaic cells 120 may be similar to the photovoltaic devices 120 depicted in FIGS. 2A and 2B. In some implementations, the array 156 of photovoltaic cells 120 can be electrically connected together with ribbons (such as ribbon 140 in FIG. 3). The PV module 150 can include a frame 152 that is disposed along at least a portion of the edges of the array for supporting the array. The frame 152 can be configured to protect the edges of the array as well as any electrical components (e.g., bus lines) that may be disposed along the edges of the array. In some implementations, the frame structure supports the array and provides a strong structural member that can be connected to other supporting structure to position the PV module at a desired angle with respect to the sun. The composition of the frame 152 can include one or more metal materials (e.g., aluminum) or rigid non-metal materials. In some implementations, the frame can be configured to provide conductive bussing to route the electricity produced by the PV module to another conductive element and to downstream electrical devices or systems.

As illustrated in FIG. 4A, some implementations can include a boundary reflector 154 (also referred to herein as a “reflector”) disposed at the periphery of the array 156, between the frame 152 and the edges of the array 156. For example, the boundary reflector 154 can be disposed along a portion of, or all of, the outside edge of the PV cells 120 that are arranged on the outer edges of the array 156. All or a portion of the outside edges of the PV cells 120 that are arranged on the outer edge of the array 156 is referred to herein as being an edge 153 of the array 156. The boundary reflector 154 can be positioned along the edge 153, and can be in contact with the edge 153. In some implementations, the boundary reflector 154 can be positioned adjacent to but not in contact with the edge 153 such that there is gap between the boundary reflector 154 and the edge 153. In some implementations, this gap can be filled with air or another material that does not absorb, or minimally absorbs, light.

The boundary reflector 154 includes a reflective surface that is configured to reflect light, that exits an edge 153 of the array 156, back through the edge 153 and into the array 156. For example, at least a portion of the light that has been caused to propagate in the array 154 and reflect from one or more internal surfaces of the PV cells in the array at relatively small angles (e.g., at angles resulting in total internal reflection), towards an edge of the array, and pass through an edge 153 of the array 156 falls incident on a reflective surface of a boundary reflector 154. The reflective surface is configured with a shape (for example, convex) that advantageously redirects light that has exited the array through an edge of a PV cell back through the edge and into the array, thereby increasing the amount of light that can be incident on PV material disposed in the array 154. Re-introducing light, that has exited the array 156 along one or more portions of an edge 153, back into the array, increases the amount of light that eventually propagates to photovoltaic material disposed in the PV cells 120 of the array 156. In some implementations, the boundary reflector 154 can include a structure with a reflective surface. In some implementations, the boundary reflector 154 includes at least one thin coating on another structure, such as, for example, a coating on an edge of the array or on a surface of the frame.

FIG. 4B is a schematic cross-sectional view of an implementation of a photovoltaic module 400 having a diffuser 402 formed on or forward a conductor 404 of a photovoltaic device 406 which includes a photovoltaic active region 407. As illustrated, the photovoltaic device 406 is in an array of photovoltaic devices 406 in a photovoltaic module 400 (similar to the module 150 of FIG. 4A). However, the diffuser 402 may be formed on the conductor 404 of any photovoltaic device 406 such as an individual photovoltaic cell, on cells in a photovoltaic module, or in a monolithically integrated module, such as a thin film photovoltaic module. For example, one or more diffusers 402 can be disposed on the ribbon 140 illustrated in FIG. 3. In some implementations, the diffuser 402 is a reflective diffuser. The diffuser 402 may be formed from any structure with the desired optical function, such as, for example, a hologram (such as a holographic diffuser), or by roughening the surface of the conductor 404. Alternatively, diffractive optical elements may be used such as diffraction gratings. The diffuser 402 may be a diffusing tape that can be adhered onto the conductors 404. In some implementations, the diffuser 402 can be a reflective film, such as 0.5 mm GORE Diffuse Reflector Product manufactured by W. L. Gore & Associates, Inc., of Newark, Del., USA. In some implementations, the diffuser 402 can have a reflectance of over 96% for light with wavelengths in the range of 400 nm to 750 nm. In some implementations, the diffuser 402 can have a diffuseness that is highly Lambertian. In some implementations the diffuser 402 is not Lambertian and the reflectance distribution is such that the light reflected from the diffuser is very likely to be subsequently totally internally reflected off of the surface 408. For example, the diffuser 402 may be more likely to reflect light at an angle greater than about 45° from normal than it is to reflect light at an angle that is less than about 45°. Alternatively, the diffuser 402 may comprise a spray-on diffuser, such as white paint sprayed onto the conductors in addition to imparting a microstructure to the conductors. Other types of diffusers may be employed. The diffuser 402 may diffuse the light in many different directions. In some implementations, the diffuser 402 may diffuse the light over 180° (i.e., ±90° from normal to the front surface of conductor 404). In some such implementations, the diffuser 402 may be a Lambertian diffuser and diffuse the light evenly over the 180°. In such implementations, some light diffused from the Lambertian diffuser will not be incident on a surface 408 at an angle greater than the total internal reflection angle and as such will not be redirected to the photovoltaic device. However, a Lambertian diffuser may diffuse enough light so as to be incident on the surface 408 at greater than the total internal reflection angle to appreciably improve the efficiency of a photovoltaic device. Since fabricating a pure Lambertian surface may be difficult given current technology, in other implementations, the diffuser 402 may diffuse the light over a range of angles, for example between 0° and 90° or 90° and 180°. It is understood that many ranges are achievable, but that practical diffusers are not perfect. Therefore, a practical diffuser configured to diffuse incident light, for example, at greater than ±45° from normal, will not diffuse all light at these angles. It is understood that the various ranges referred to indicate that less than 50% peak transmission is diffused (reflected) at angles outside of the given range. In some implementations, the diffuser 402 may diffuse appreciable light from 50° from normal to as high as 85° degrees from normal. In some implementations, the intensity of light reflected from the diffuser 402 in some range of angles greater than the total internal reflection angle is greater than 70% of the light intensity reflected at the peak intensity angle (i.e., the angle with maximum reflected intensity). For example, the diffuser 402 may reflect greater than or equal to 70% of the light intensity reflected at the peak intensity angle in the range of 42° to 55° from normal (of the photovoltaic device surface). In some implementations, the intensity of light reflected from the diffuser 402 in some range of angles greater than the total internal reflection angle is greater than 50% of the light intensity reflected at the peak intensity angle.

As illustrated in FIG. 4B, the diffuser 402 may allow some of the light reflected from the conductor (or other non-electricity-generating surface within the photovoltaic module) to be totally internally reflected off of the surface 408. As illustrated, the surface 408 is formed at the air-glass interface of a cover glass 410, such as a glass plate or other high-index plate formed forward of the conductor 402. However, the device may be packaged in other ways. As illustrated, some portion of the light may be reflected normal or near normal to the surface 408 and escape. Preferably, the diffuser 402 diffuses a substantial amount of light such that the diffused light is then incident on the surface 408 at an angle greater than the critical angle. In any case, even pure Lambertian diffusion can result in a significant improvement in efficiency. Hence, in implementations where the diffusion is non-Lambertian and the diffuser 402 may diffuse light such that a greater proportion of the light is then incident on the surface 408 at an angle greater than the critical angle, even greater improvements in efficiency are possible. For example, in some implementations, less than 10% of the light is reflected within ±10° of normal.

As illustrated, the photovoltaic module 400 comprises photovoltaic devices 406 that are encapsulated in an encapsulation layer 412, which may be made of ethylene vinyl acetate (EVA). The photovoltaic module 400 also comprises a backsheet 414. Typically, the layers will be surrounded by a frame 416, which may be made of a metal, such as aluminum. However, in various other implementations, more or fewer layers may be used, and other suitable materials may also substitute those mentioned above.

As mentioned above, in some implementations, a photovoltaic module can include an array of photovoltaic cells with one or more diffusers covering at least a portion of a forward surface of the array. In some implementations, for example, diffusers can account for between about 5% and 30% of the forward (e.g., light-facing) surface of an array, or, as another example, between about 10% and 20% of the forward surface area of an array, for example, between 15% and 30%. As used herein, the “forward” surface area of the array refers to the light-facing surface of the array; in other words, the surface of the array that is configured to receive incident light for generating power.

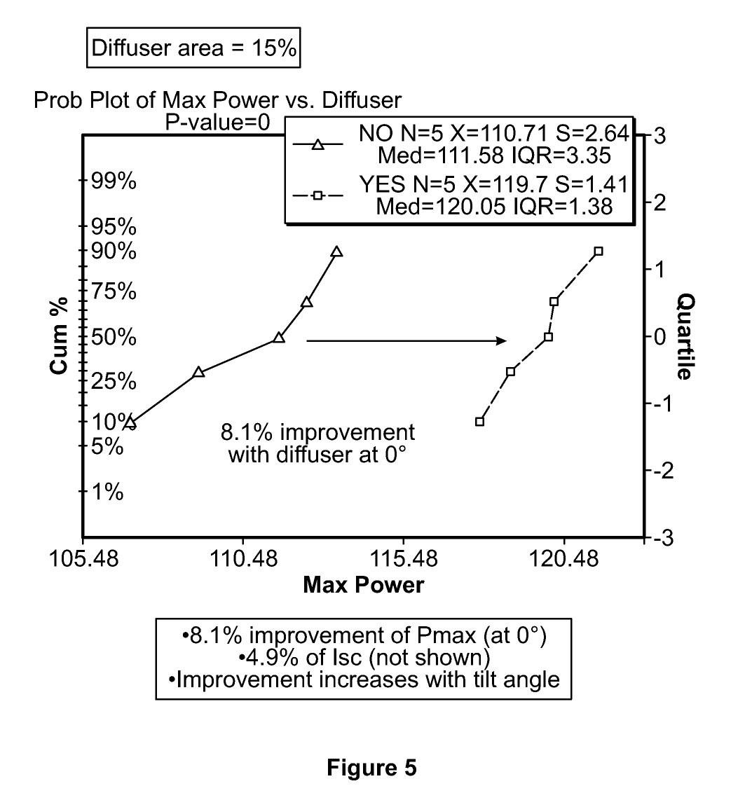

FIG. 5 is an example of a graph of experimental data showing the maximum power collected from two different configurations of a single photovoltaic cell, one without diffusers and one including diffusers. An artificial light source with standard optical power equal to one sun at normal incidence was used. The horizontal axis in FIG. 5 is the maximum power for each photovoltaic cell, while the vertical axis is the statistical probability resulting from analysis of the data. Specifically, FIG. 5 shows experimental data from five separate individual photovoltaic cells without diffusers and from five photovoltaic modules with diffusers covering approximately 15% of the forward surface of the cell. As shown in FIG. 5, in some implementations, the provision of diffusers covering approximately 15% of the forward surface area of an array can increase the median maximum power by approximately 8.1%, which, in at least one implementation, corresponds to an improvement of 4.9% in short circuit current.

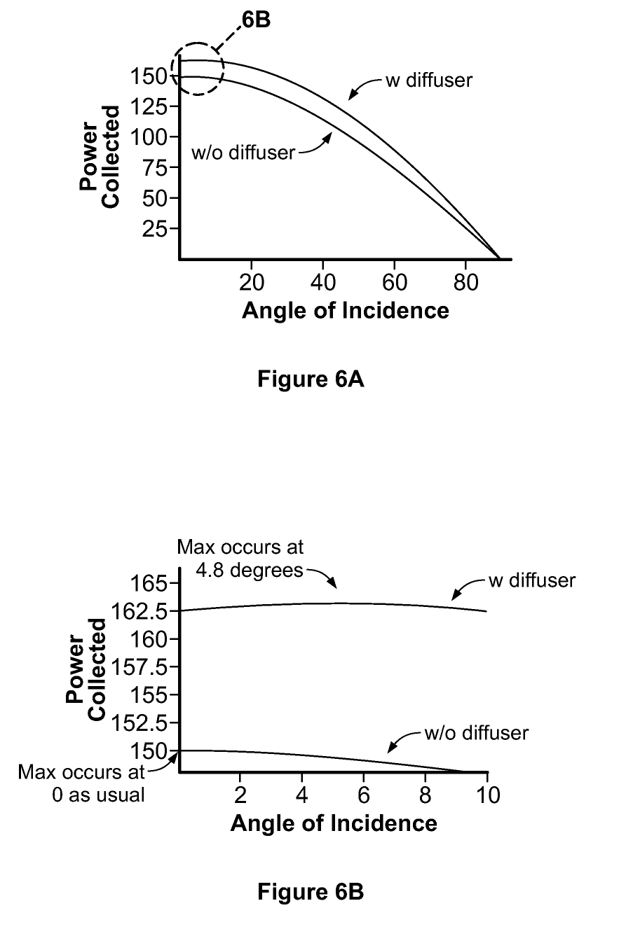

FIG. 6A is an example of a graph of modeled data showing the power collected from two different photovoltaic modules, one without diffusers and one including diffusers, with the modules disposed at various angles relative to the direction of incoming light. The model assumes a module with 15% efficiency and an area of 1. The model also assumes that the diffusers are ideal Lambertian diffusers. As shown in FIG. 6A, the module including the diffusers exhibits an improved power performance over the module without diffusers, both when pointed directly at the sun (i.e., at a 0° angle of incidence) and also when tilted away from the sun (i.e., at a greater-than-0° angle of incidence), for example along a first axis and/or a second axis. It should be noted that the behavior indicated in FIG. 6A is symmetric about the origin and, thus, the power collected from a panel oriented at a negative angle (such as −10° away from normal is the same as the power collected from a panel oriented at a corresponding positive angle (such as +10°.

FIG. 6B is a close-up of the portion of FIG. 6A indicated by dashed line 6B. FIG. 6B illustrates that the addition of the diffuser actually changes the tilt angle at which maximum power is achieved. In a module without a diffuser, the maximum power is collected when the module is pointed directly at the sun (i.e., when the module is oriented to receive solar rays at a 0° angle of incidence). However, in the module with a diffuser, the maximum power is collected when the module is oriented at an angle offset from the sun (i.e., when the module is oriented to receive solar rays at a greater-than-0° angle of incidence). In the illustrated implementation, the module achieves maximum power when oriented to receive solar rays at a 4.8° angle of incidence. Thus, in some implementations, the maximum power achieved by a photovoltaic module can be improved by orienting the module at an angle offset from the sun. Without being limited by any theory, it is believed that the particular characteristics of any given diffuser will affect the offset angle at which the maximum power is achieved.

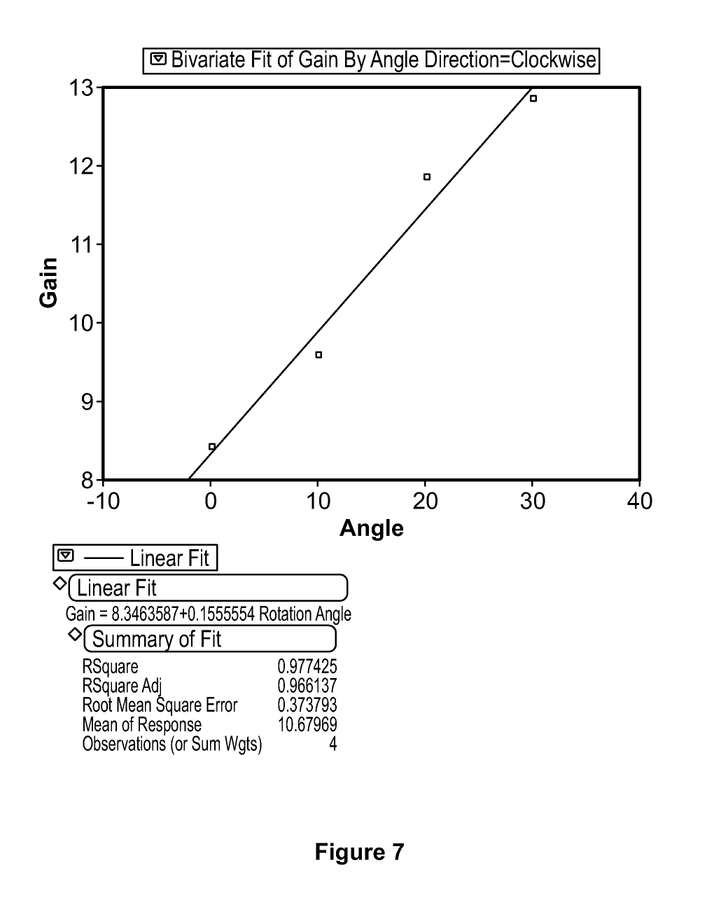

FIG. 7 is an example of a graph of experimental data showing the gain (in percent improvement) achieved by a photovoltaic cell including diffusers, as compared to a photovoltaic module without diffusers, at various angles relative to a standard artificial light source having optical power equal to one sun (that is a light source disposed so as to have various angles of incidence relative to the photovoltaic cell). As shown in FIG. 7, at a 0° angle of incidence, a cell including diffusers exhibits a power gain of 8.35%. As the tilt angle of the module (with respect to the sun) is increased from 0° to 30° or higher, the power gain increases in a linear fashion. In other words, the percent improvement (in contrast to absolute improvement shown in FIGS. 6A and 6B) at a given angle of incidence for a photovoltaic cell having diffusers disposed thereon increases when compared to a photovoltaic cell without diffusers at the same angle of incidence. As can be understood from FIG. 7, the provision of diffusers in a photovoltaic module or panel can improve the power collection of a photovoltaic module, such as a fixed photovoltaic module or a sun-tracking photovoltaic module. Thus, in some implementations of sun-tracking photovoltaic modules, one or more sun-tracking photovoltaic modules can be configured to update their positions less frequently than conventional tracking systems, so as to maintain the sun's rays at a non-zero angle of incidence throughout a greater portion of the day.

Conventional solar panel systems are either installed at a fixed angle with respect to the sun, or are movable throughout the day to track the position of the sun. These movable systems are also referred to as “tracking” systems. Some movable systems are single-axis trackers. Single-axis trackers have one degree of freedom that acts as an axis of rotation. The axis of rotation of single axis trackers can be aligned along a true North meridian. It is possible to align them in any cardinal direction with advanced tracking algorithms. There are several common implementations of single axis trackers. These include horizontal single axis trackers (HSAT), vertical single axis trackers (VSAT), tilted single axis trackers (TSAT) and polar aligned single axis trackers (PASAT). The orientation of the module with respect to the tracker axis is important when modeling performance.

The axis of rotation for a horizontal single axis tracker is horizontal with respect to the ground. The simple geometry means that keeping all of the axes of rotation parallel to one another is all that is required for appropriately positioning the trackers with respect to one another. Appropriate spacing can maximize the ratio of energy production to cost, this being dependent upon local terrain and shading conditions and the time-of-day value of the energy produced. Horizontal trackers can have the face of the module oriented parallel to the axis of rotation. As a module tracks, it sweeps a cylinder that is rotationally symmetric around the axis of rotation. The axis of rotation for vertical single axis trackers is vertical with respect to the ground. These trackers rotate from east to west over the course of the day. Such trackers are more effective at high latitudes than are horizontal axis trackers. Vertical single axis trackers can have the face of the module oriented at an angle with respect to the axis of rotation. As a module tracks, it sweeps a cone that is rotationally symmetric around the axis of rotation.

Dual axis trackers have two degrees of freedom that act as axes of rotation. These axes are typically normal to one another. The axis that is fixed with respect to the ground can be considered a primary axis. The axis that is referenced to the primary axis can be considered a secondary axis. There are several common implementations of dual axis trackers. They are classified by the orientation of their primary axes with respect to the ground. Two common implementations are tip-tilt dual axis trackers (TTDAT) and azimuth-altitude dual axis trackers (AADAT). The orientation of the module with respect to the tracker axis is important when modeling performance. Dual axis trackers typically have modules oriented parallel to the secondary axis of rotation.

A tip-tilt dual axis tracker has its primary axis horizontal to the ground. The secondary axis is then typically normal to the primary axis. The posts at either end of the primary axis of rotation of a tip-tilt dual axis tracker can be shared between trackers to lower installation costs. Field layouts with tip-tilt dual axis trackers are very flexible. The simple geometry means that keeping the axes of rotation parallel to one another is all that is required for appropriately positioning the trackers with respect to one another. The axes of rotation of tip-tilt dual axis trackers can be aligned either along a true north meridian or an east-west line of latitude. It is possible to align them in any cardinal direction with advanced tracking algorithms. An azimuth-altitude dual axis tracker has its primary axis vertical to the ground. The secondary axis is then typically normal to the primary axis.

Typically, in order to maximize the overall power collection of a fixed system over the course of the year, fixed systems are oriented to face true south (or true north, in the southern hemisphere), and are tilted at a fixed angle selected based on the latitude.

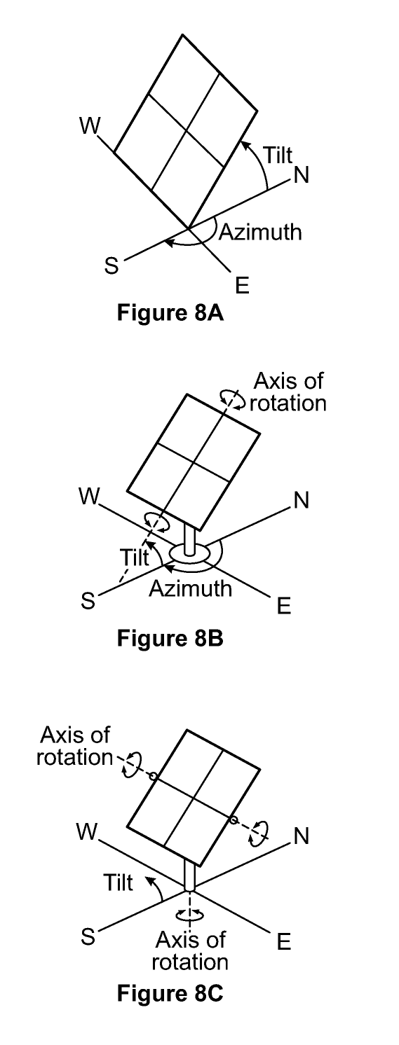

FIG. 8A is an example a fixed system, and shows a solar panel facing south (i.e., with an azimuth angle of 180°) at a fixed tilt angle.

Conventional tracking systems are typically configured to point the panel(s) directly at the sun, or at least to closely track the position of the sun, for at least a large portion of the day, so that the sun's rays have as close to a zero angle of incidence as possible on the panel(s). FIG. 8B is an example of a tilted single-axis tracking system and shows a solar panel facing south, with its axis of rotation extending in the north-south plane, so that the panel can track the azimuth angle of the sun throughout the day. FIG. 8C is an example of a dual-axis tracking system and shows a solar panel facing south, with a first horizontal axis of rotation and a second vertical axis of rotation. The panel can be moved about the first and second axes to maintain the panel pointed directly at the sun throughout the day.

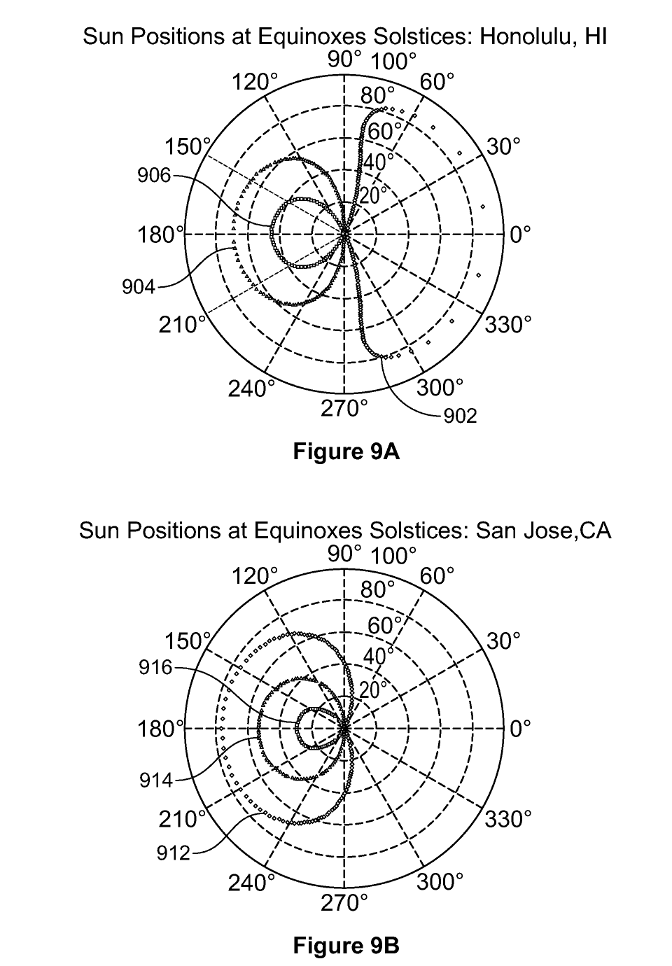

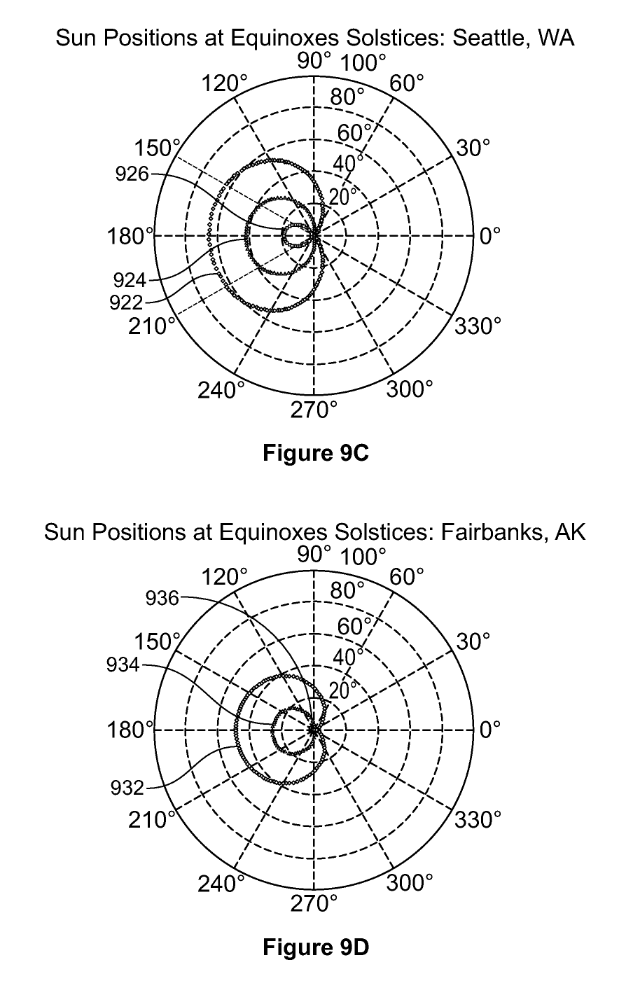

FIGS. 9A-9D are examples of graphs showing the path of the sun at various geographical locations, throughout various days of the year. For each point in each graph, the radial distance from the center (as indicated by circles 20°, 40°, 60°, etc.) represents the elevation angle of the sun at a particular time, and the angular position (as indicated by radial lines 0°, 30°, 60°, 90°, etc.) represents the azimuth angle of the sun at that same time. FIG. 9A shows the path of the sun in Honolulu, Hi. at the summer solstice (line 902), at the spring and autumnal equinoxes (line 904), and at the winter solstice (line 906). FIG. 9B shows the path of the sun in San Jose, Calif. at the summer solstice (line 912), at the spring and autumnal equinoxes (line 914), and at the winter solstice (line 916). FIG. 9C shows the path of the sun in Seattle, Wash. at the summer solstice (line 922), at the spring and autumnal equinoxes (line 924), and at the winter solstice (line 926). FIG. 9D shows the path of the sun in Fairbanks, Ak. at the summer solstice (line 932), at the spring and autumnal equinoxes (line 934), and at the winter solstice (line 936). In each of these graphs, for each day, the point along the 180° indicates the elevation angle of the sun at solar noon. As described herein above, conventional solar tracking systems are designed to orient their solar panel(s) directly toward the sun as much as possible throughout the day, i.e., to track the sun path lines (see FIGS. 9A-9D) as closely as possible given the tracking capabilities of the system. Put another way, conventional systems are designed to match, as closely as possible, one of or both of the azimuth angle and elevation angle of the sun as these angles change throughout the day.

In some implementations, however, a solar tracking system can be designed to maintain an offset between the orientation of the panel and the position of the sun in the sky. In other words, a tracking system can be configured to follow a path that is offset from the sun path lines shown in FIGS. 9A-9D. For example, a tracking system can be configured to follow a path that is radially offset from the sun path lines shown in FIGS. 9A-9D (e.g., a path that tracks the azimuth angle of the sun as closely as possible throughout the day, while orienting the panel at an elevation angle which is higher or lower than the elevation angle of the sun for each given azimuth angle). As another example, a tracking system can be configured to follow a path that is temporally offset from the sun path lines shown in FIGS. 9A-9D (e.g., a path that tracks the elevation angle of the sun as closely as possible, while orienting the panel at an azimuth angle which is higher or lower than the azimuth angle of the sun for each given elevation angle). In some implementations, a combination of azimuth and elevation angle offsets can be used to take advantage of the increase in power which results from orienting a PV panel with diffusers at an offset angle from the sun.

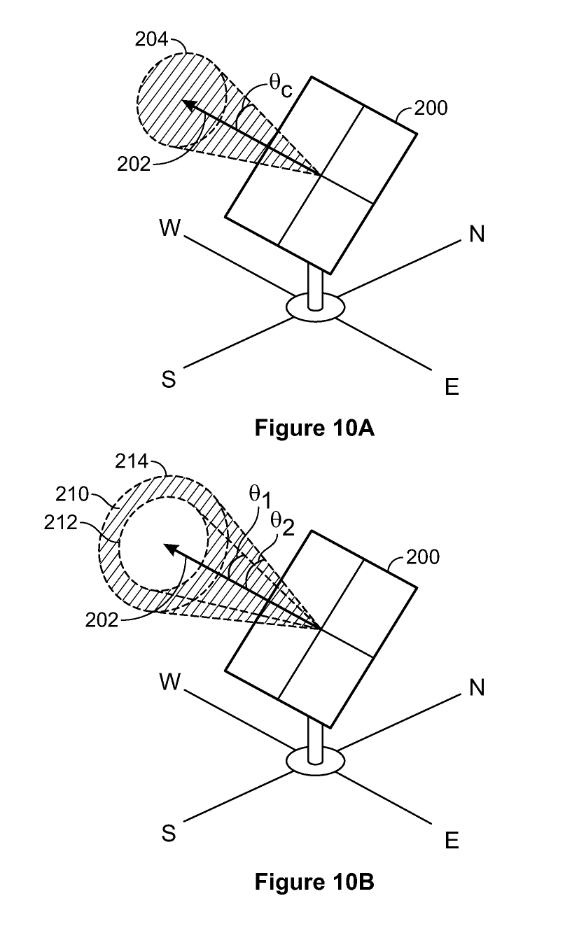

In some implementations, a tracking PV system can be configured to maintain its PV panel(s) within a cone about the normal of a panel. FIG. 10A is an example of a schematic drawing illustrating a cone about the normal of a solar panel, in accordance with one such implementation. As shown in FIG. 10A, a panel 200 has a generally planar face defining a normal 202. The panel can be movable (e.g., about one or more axes) so as to track the position of the sun, for example as described herein. In contrast to conventional systems which update the position of the panel 200 so as to maintain the normal 202 aimed directly at the sun, however, implementations can update the position of the panel 200 based upon whether the solar angle of incidence on the panel falls within a cone 204 of an angle θ_{C} about the normal 202. The angle θ_{C} can be, for example, at least 3°, at least 4°, at least 5°, at least 6°, at least 7°, at least 8°, at least 9°, at least 10°, at least 12°, at least 15°, at least 20°, at least 25°, at least 30°, at least 40°, at least 50°, at least 60°, or within a range defined by any of these angles.

In other implementations, a tracking PV system can be configured to maintain its PV panel(s) within a zone defined by first and second cones about the normal of a panel. FIG. 10B is an example of a schematic drawing illustrating a zone defined by first and second cones about the normal 202 of the solar panel 200, in accordance with one such implementation. In FIG. 10B, a panel 200 has a generally planar face defining a normal 202. The panel 200 can be movable (e.g., about one or more axes) so as to track the position of the sun, for example as described herein. In contrast to conventional systems which update the position of the panel 200 so as to maintain the normal 202 aimed directly at the sun, however, implementations can update the position of the panel 200 based upon whether the solar angle of incidence on the panel falls within a zone 210 defined by first and second cones 212, 214 about the normal 202. The first cone 212 can be a cone of an angle Θ₁ about the normal 202. The second cone 214 can be a cone of an angle Θ₂ about the normal 202. The angle Θ₂ can be greater than the angle Θ₁. In some implementations, the angle Θ₁ can be, for example, at least 3°, at least 4°, at least 5°, at least 6°, at least 7°, at least 8°, at least 9°, at least 10°, or within a range defined by any of these angles. In some implementations, the angle Θ₂ can be, for example, at least 5°, at least 6°, at least 7°, at least 8°, at least 9°, at least 10°, at least 12°, at least 15°, at least 20°, at least 25°, at least 30°, or within a range defined by any of these angles. In some implementations angle Θ₁ can be at least 4.3° and angle Θ₂ can be at least 5.3°; or angle Θ₁ can be at least 3.8° and angle Θ₂ can be at least 5.8°.

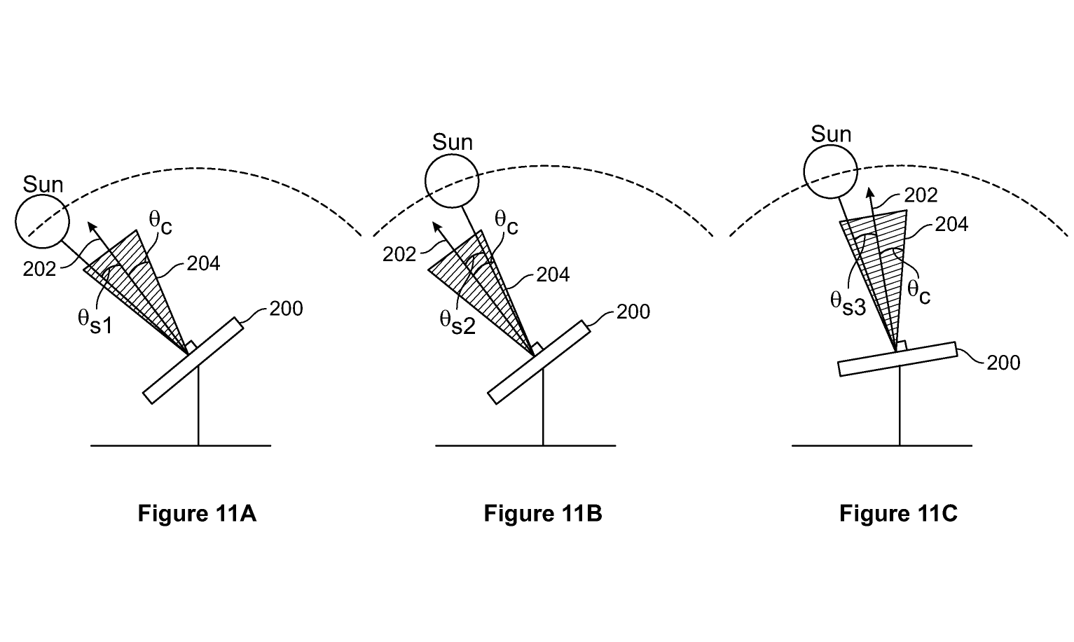

FIGS. 11A-11C are examples of schematic drawings illustrating a method for updating the position of a solar panel based upon whether the solar angle of incidence on the panel falls within a cone about the normal, in accordance with an implementation. As shown in FIG. 11A, early in the day, the sun is at a relatively low angle in the sky, and the sun's rays are incident upon the solar panel 200 at an angle Θ_{S1} which is less than the angle Θ_{C} defining the cone about the normal 202. As shown in FIG. 11B, a little later in the day, the sun has moved to a slightly higher angle in the sky, and the sun's rays are incident upon the solar panel 200 at an angle Θ_{S2}. Because the angle Θ_{S2} is also less than the angle Θ_{C}, the sun's rays still fall within the cone 204, and the position of the panel 200 remains the same as it was in FIG. 11A. Only when the angle of incidence of the sun on the panel 200 becomes greater than the angle Θ_{C} (i.e., shortly after the time illustrated in FIG. 11B) is the panel moved to re-orient the cone 204 with respect to the solar rays. As shown in FIG. 11C, the panel 200 is moved to a new position, so that the sun's rays (which would have fallen outside the cone 204 in the position shown in FIG. 11B) are now incident upon the solar panel 200 at an angle Θ_{S3} which falls within the cone 204. In some implementations, the panel 200 can be moved to a position in which the angle Θ_{S3} falls in an outer region of the cone 204 (away from the normal 202), so that the panel 200 can remain stationary for as long as possible before the sun again moves out of the cone 204 (i.e., before the panel is moved again).

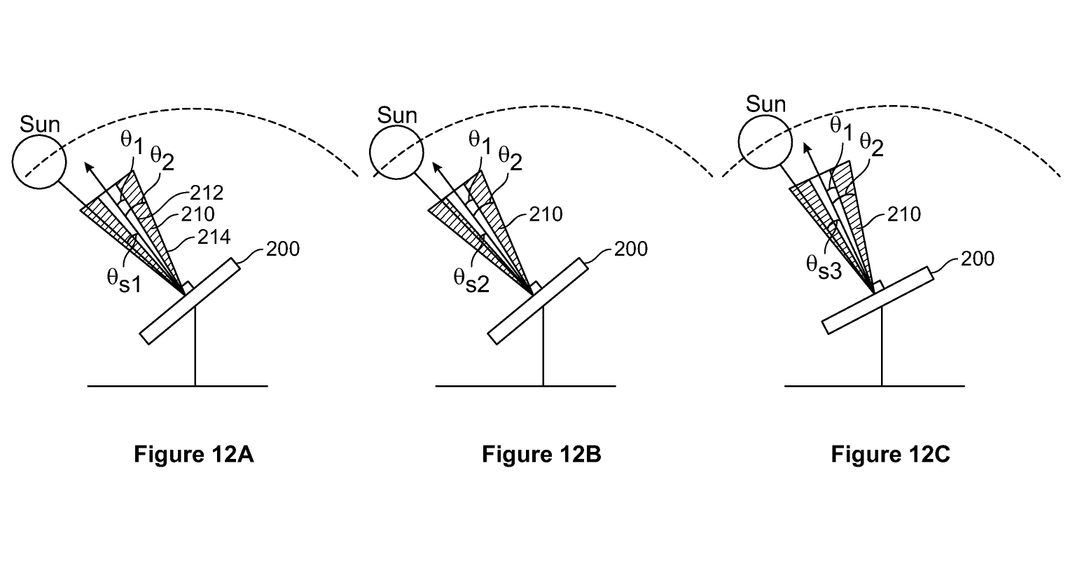

FIGS. 12A-12C are examples of schematic drawings illustrating a method for updating the position of a solar panel based upon whether the solar angle of incidence on the panel falls within a zone defined by first and second cones about the normal, in accordance with another implementation. As shown in FIG. 12A, early in the day, the sun is at a relatively low angle in the sky, and the sun's rays are incident upon the solar panel 200 at an angle Θ_{S1} which is greater than the angle Θ₁ defining the inner cone 212 and less than the angle Θ₂ defining the outer cone 214 about the normal 202. Thus, in the position illustrated in FIG. 12A, the sun's rays are incident upon the panel 200 at an angle which falls within the zone 210. As shown in FIG. 12B, a little later in the day, the sun has moved to a slightly higher position in the sky, and the sun's rays are incident upon the solar panel 200 at an angle θ_{S2}. Because the angle θ_{S2} also falls within the zone 210, the position of the panel 200 remains the same as it was in FIG. 12A. Only when the angle of incidence of the sun on the panel 200 falls outside the zone 210 (e.g., shortly after the time illustrated in FIG. 12B) is the panel moved to re-orient the zone 210 with respect to the solar rays. As shown in FIG. 12C, the panel 200 is moved to a new position, so that the sun's rays (which would have fallen outside the zone 210 in the position shown in FIG. 12B) are now incident upon the solar panel 200 at an angle θ_{S3} which falls within the zone 210. In some implementations, the panel 200 can be moved to a position in which the angle θ_{S3} falls in an outer region of the zone 210 (away from the normal 202), so that the panel 200 can remain stationary for as long as possible before the sun again moves out of the zone 210 (i.e., before the panel is moved again). Accordingly, some configurations can be configured to keep the panel facing not directly at the sun, but at an offset angle from the sun, throughout the day.

In some implementations, updating the position of the panel 200 so that the solar angle of incidence falls within a cone (or zone) about the normal can involve moving the panel about one or more axes. As will be understood by one of skill in the art, several tracking panels as described herein can be provided in an array, such as, for example, an array rated to produce at least 1 MW of power. In some implementations, the solar angle of incidence can be determined using a lookup table specific to the geographical location at which the panel is installed. In some implementations, a panel (or an array including multiple panels) can include one or more photosensors or photodiodes configured to sense the solar angle of incidence on the panel(s) and to provide feedback to a controller that controls movement of the panel(s) about one or more axes in accordance with the methods described herein. The panel(s) can be moved in any direction that places the solar angle of incidence back within the cone (or zone). In some implementations, the controller can be configured to move the panel(s) so that the solar angle of incidence on the panel(s) falls on an opposite side of the cone (or zone, as the case may be) as it did immediately prior to the movement of the panel(s), so as to maximize the amount of time the solar angle of incidence will remain in the cone (or zone) before the panel(s) are moved again.

It will be understood that, at least for a single-axis tracking system, at certain tilt angles (with respect to the horizontal) and at certain latitudes, it may only be possible to maintain the solar angle of incidence within a defined cone (or zone, as the case may be) during a portion of a day. In some implementations, updating the position of a solar panel based upon whether the solar angle of incidence on the panel falls within a cone (or zone, as the case may be) can be performed for a portion of a day, including mid-day or solar noon. In some implementations, the portion of a day can include at least 4 hours, at least 6 hours, at least 8 hours, at least 10 hours, at least 12 hours, or more. It is understood that for single-axis solar systems, in some situations at certain times of the day in certain times of the year, for a given angle Θ_{C} and for a given tilt angle, at a given location, incident solar light may always be outside the cone 204, and in such situations, the panel 200 can be updated throughout the day in a way so as to improve the power generated by the panel 200 if left stationary. For example, if angle Θ_{C} is set to be relatively narrow, for example 10°, then there may be times in the day during the summer and/or winter, for example, when incident solar radiation is outside the cone 204 and it is not possible to reorient the panel 200 so that the solar radiation can be within the cone. Because of this, in some implementations, Θ_{C} can be programmed to be different at different times of the year. That is, in some implementations, the system controlling panel 200 or an array of panels such as panel 200 can be configured to have two or more values for Θ_{C} depending the time of year. In some implementations, Θ_{C} is programmed to be larger in winter and/or summer than it is in the fall and/or spring.

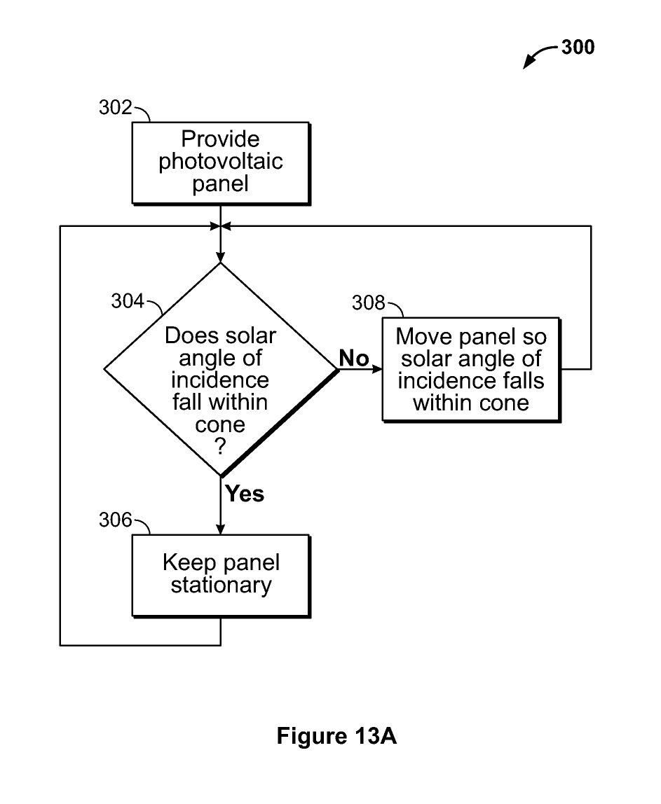

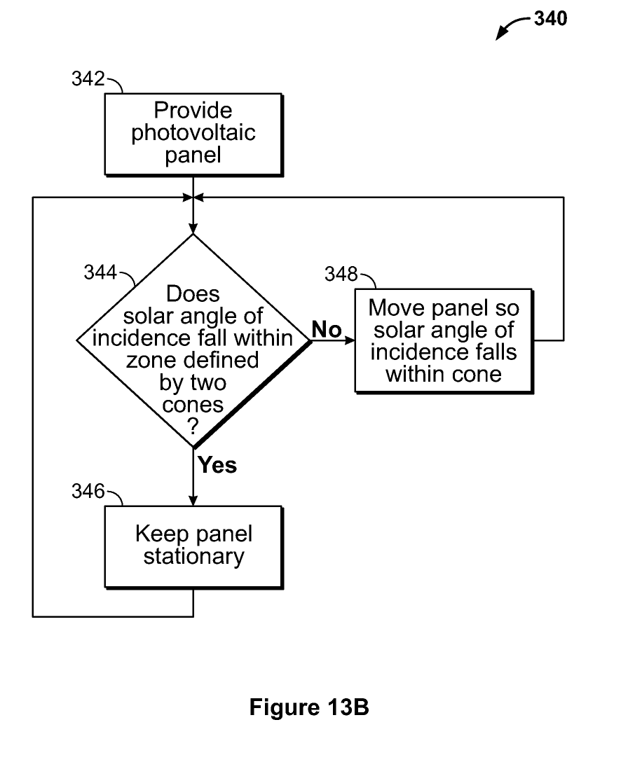

FIGS. 13A and 13B are examples of process diagrams illustrating methods for producing power from a photovoltaic panel in accordance with some implementations. As shown in FIG. 13A, a method 300 includes providing a photovoltaic panel at block 302. The photovoltaic panel can have any suitable configuration, for example as described herein. The photovoltaic panel can have a light-receiving surface area, at least a portion of which forms a plane defining a normal. At block 304, the position of the panel can be updated based upon whether the solar angle of incidence on the panel falls within a cone of about a normal of the panel. If the solar angle of incidence on the panel does fall within the cone, the panel can remain stationary, as illustrated in block 306. If the solar angle of incidence on the panel does not fall within the cone, the panel can be moved so that the solar angle of incidence falls within the cone, as illustrated in block 308.

As shown in FIG. 13B, a method 340 includes providing a photovoltaic panel at block 342. The photovoltaic panel can have any suitable configuration, for example as described herein. The photovoltaic panel can have a light-receiving surface area, at least a portion of which forms a plane defining a normal. At block 344, the position of the panel can be updated based upon whether the solar angle of incidence on the panel falls within a zone defined by two cones about a normal of the panel. If the solar angle of incidence on the panel does fall within the zone, the panel can remain stationary, as illustrated in block 346. If the solar angle of incidence on the panel does not fall within the zone, the panel can be moved so that the solar angle of incidence falls within the zone, as illustrated in block 348. After block 346 and/or block 348, the process can return to block 344 at which the solar angle of incidence may again be evaluated. In some implementations, the process can cycle through blocks 344, 346, and/or 348 for at least a portion of a day, including solar noon. In some implementations, the process can cycle through blocks 344, 346, and/or 348 for a portion of a day including at least 4 hours, at least 6 hours, at least 8 hours, at least 10 hours, at least 12 hours, or more.

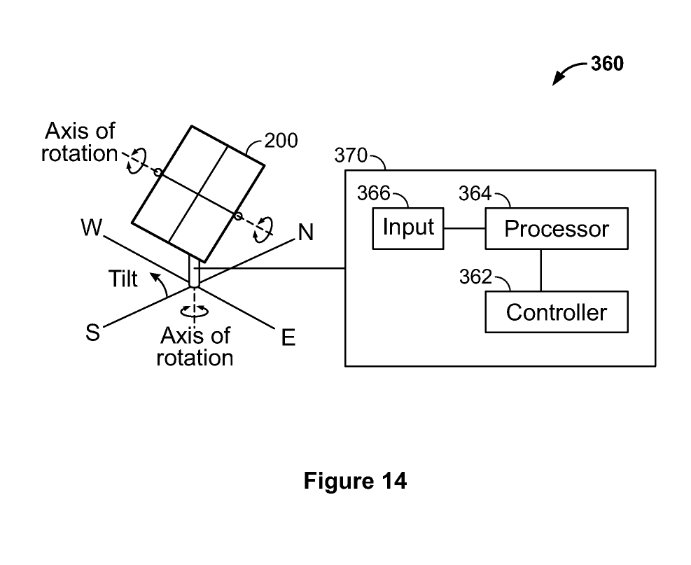

FIG. 14 shows an example of a system block diagram illustrating a solar tracking system in accordance with one implementation. As shown in FIG. 14, a solar tracking system 360 includes one or more solar panels 200, each of which can be movable about one or more axes. The solar tracking system 360 can also include a control system 370. The control system 370 can include a controller 362 configured to control the movement of one or more of the panels 200. The controller 362 can be connected to a processor 364 which receives input 368 about the angle of incidence of the sun, and processes that input to determine movement control information for the controller 362. The input 368 can be, for example, feedback from one or more sensors disposed on one or more of the panel(s) 200, or information from a lookup table specific to the geographical location at which the panel(s) 200 are installed. The processor 364 can include a microcontroller, CPU, or logic unit to control operation of the controller 362. The control system 370 can be configured to process the input 368 intermittently (e.g., at 5, 10, 15, or 20 minute intervals) or continuously throughout a portion of a day. The control system 370 can also be configured to effect movement of the panel(s) 200 only when the input 368 indicates that the angle of incidence of the sun is outside of a specified cone or zone (as the case may be) about a normal to the panel 200, as illustrated, for example, in FIGS. 11A-11C and 12A-12C, respectively.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with the disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the photovoltaic cell as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of producing power from a photovoltaic panel, the method comprising:
providing the photovoltaic panel, at least a portion of the photovoltaic panel defining a plane, the plane defining a normal; and
updating the position of the panel during at least a portion of a day, the portion of the day including solar noon, wherein updating the position of the panel is based upon whether the solar angle of incidence on the panel falls within a cone defined by an angle of at least 10° about the normal such that
when the solar angle of incidence falls within the cone, the panel remains stationary, and
when the solar angle of incidence falls outside the cone, the panel is moved so that the solar angle of incidence falls within the cone.

2. The method of claim 1, wherein updating the position of the panel includes rotating the panel about at least a first axis.

3. The method of claim 2, wherein the first axis extends in a north-south plane.

4. The method of claim 2, wherein the first axis extends in a horizontal direction.

5. The method of claim 2, wherein updating the position of the panel includes rotating the panel about a second axis.

6. The method of claim 5, wherein the second axis extends in an east-west plane.

7. The method of claim 5, wherein the first axis extends in a vertical direction.

8. The method of claim 1, wherein the cone is defined by an angle of about 10° about the normal.

9. The method of claim 1, wherein the cone is defined by an angle of about 20° about the normal.

10. The method of claim 1, wherein the cone is defined by an angle of about 30° about the normal.

11. The method of claim 1, wherein the portion of the day includes at least four hours.

12. The method of claim 1, wherein the portion of the day includes at least eight hours.

13. The method of claim 1, wherein the portion of the day includes at least twelve hours.

14. The method of claim 1, wherein the photovoltaic panel includes one or more diffusers.

15. The method of claim 14, wherein the one or more diffusers are Lambertian or near-Lambertian diffusers.

16. The method of claim 14, wherein the one or more diffusers account for at least 5% of a light-receiving surface area of the photovoltaic panel.

17. The method of claim 14, wherein the diffusers account for between about 10% and 20% of a light-receiving surface area of the photovoltaic panel.

18. The method of claim 14, wherein the one or more diffusers are configured to reflect more light at an angle greater than about 45° from the normal than to reflect light at an angle that is less than about 45° from the normal.

19. The method of claim 1, wherein an amount of power collected for the portion of the day is increased by at least 3% as compared to a method which moves an array of solar cells so that the array is oriented directly at the sun for the portion of the day.

20. A method of producing power from a photovoltaic panel, the method comprising:
providing the photovoltaic panel, at least a portion of the photovoltaic panel defining a plane, the plane defining a normal; and
updating the position of the panel during at least a portion of a day based upon the solar angle of incidence on the panel, the portion of the day including solar noon, wherein
when the solar angle of incidence falls within a zone defined by first and second cones about the normal axis, the panel remains stationary, and
when the solar angle of incidence falls outside the zone, the panel is moved so that the solar angle of incidence falls within the zone.

21. The method of claim 20, wherein the first cone is defined by an angle of at least 4.3° about the normal and the second cone is defined by an angle of less than 5.3° about the normal.

22. The method of claim 20, wherein the first cone is defined by an angle of at least 3.8° about the normal and the second cone is defined by an angle of less than 5.8° about the normal.

23. The method of claim 20, wherein updating the position of the panel includes rotating the panel about at least a first axis.

24. The method of claim 23, wherein the first axis extends in a north-south plane.

25. The method of claim 23, wherein updating the position of the panel includes rotating the panel about a second axis.

26. The method of claim 25, wherein the second axis extends in an east-west plane.

27. A system for producing electricity, the system comprising:
means for converting solar radiation to electricity, the converting means extending generally in a plane, the plane defining a normal; and
means for updating the position of the converting means during at least a portion of a day, the portion of the day including solar noon, based on whether the solar angle of incidence on the plane falls within a cone of at least 10° about the normal such that
when the solar angle of incidence falls within the cone, the converting means remains stationary, and
when the solar angle of incidence falls outside the cone, the converting means is moved so that the solar angle of incidence falls within the cone.

28. The system of claim 27, wherein the cone is defined by an angle selected from the group consisting of 10°, 20°, and 30° about the normal.
